(19) United States
(12) Patent Application Publication
(10) Pub. No.: US 2024/0395691 A1
(43) Pub. Date: Nov. 28, 2024

(54) SEMICONDUCTOR DEVICE

(71) Applicant: FUJI ELECTRIC CO., LTD., Kawasaki-shi (JP)

(72) Inventors: Yuta EBUKURO, Kawasaki-shi (JP); Akio YAMANO, Kawasaki-shi (JP)

(73) Assignee: FUJI ELECTRIC CO., LTD., Kawasaki-shi (JP)

(21) Appl. No.: 18/790,691

(22) Filed: Jul. 31, 2024

Related U.S. Application Data
(63) Continuation of application No. PCT/JP2023/025247, filed on Jul. 7, 2023.

(30) Foreign Application Priority Data
Aug. 29, 2022 (JP) 2022-135711

(51) Int. Cl. H01L 23/498; H01L 23/00; H01L 25/07

(52) U.S. Cl. CPC H01L 23/49844; H01L 23/49811; H01L 24/48; H01L 25/072; H01L 24/45; H01L 2224/45124; H01L 2224/45144; H01L 2224/45147; H01L 2224/48225; H01L 2924/13055; H01L 2924/3511

(57) ABSTRACT

A semiconductor device includes first and second terminals, a first conductor having a plurality of semiconductor elements arranged side by side in an arrangement direction thereon, and electrically connecting the plurality of semiconductor elements to the first terminal via first wiring, and a second conductor electrically connecting the plurality of semiconductor elements on the first conductor to the second terminal via second wiring. The first and second terminals are respectively located on opposite sides of the first and second conductors with respect to the arrangement direction. The second conductor has a shoulder portion that extends in a width direction perpendicular to the arrangement direction and two extended portions arranged at the shoulder portion spaced apart from each other in the width direction. The two extended portions respectively extend in the arrangement direction and are electrically connected to the plurality of semiconductor elements.

### CROSS REFERENCE TO RELATED APPLICATIONS

This is a continuation application of International Application PCT/JP2023/025247 filed on Jul. 7, 2023 which claims priority from a Japanese Patent Application No. 2022-135711 filed on Aug. 29, 2022, the contents of which are incorporated herein by reference.

### BACKGROUND

### Technical Field

The present invention relates to a semiconductor device.

### Related Art

A semiconductor device has a substrate, on which semiconductor elements such as an insulated gate bipolar transistor (IGBT), a power metal oxide semiconductor field effect transistor (MOSFET), and a free wheeling diode (FWD) are provided, and is used in an inverter device and the like (see, for example, JP 2005-252305 A, WO 2013/179547 A, JP 2009-206140 A, JP 2021-177519 A, JP 2021-141220 A, WO 2019/202866 A).

In this type of semiconductor device, there is a semiconductor device in which a plurality of semiconductor elements are arranged side by side in a row between main terminals for external connection (see, for example, JP 2005-252305 A and WO 2013/179547 A).

### SUMMARY

In particular, in a semiconductor device or the like having a reverse conducting (RC)-IGBT element in which an IGBT and an FWD are integrated, when a plurality of semiconductor elements are arranged side by side in a row between main terminals for external connection as described above, a portion where a current flow is concentrated in the arrangement direction of the semiconductor elements is likely to occur in a conductor such as a copper pattern. When the current flow concentrates in the arrangement direction of the semiconductor elements as described above, for example, warpage occurs in the heat dissipation plate located on the lower surface side of the circuit board on which the conductor is provided. When a gap is generated between the heat dissipation plate and a heat sink located on the lower surface side of the heat sink due to the warpage, heat generation is concentrated at a portion where the current flow is concentrated in the arrangement direction. When heat generation is concentrated in this manner, it is difficult to increase the output current.

It is an object of the present invention to disperse heat generation due to current flow in a semiconductor device including a plurality of semiconductor elements located side by side in a row.

According to an aspect, a semiconductor device includes: a plurality of semiconductor elements located side by side in a row; a first terminal and a second terminal; a first conductor electrically connecting the first terminal and the plurality of semiconductor elements to each other; and a second conductor electrically connecting the plurality of semiconductor elements and the second terminal to each other. The first terminal is located on one side in an arrangement direction of the plurality of semiconductor elements with respect to the plurality of semiconductor elements, the first conductor, and the second conductor. The second terminal is located on the other side in the arrangement direction with respect to the plurality of semiconductor elements, the first conductor, and the second conductor. The second conductor has two divided pieces, of which both sides in a width direction perpendicular to the arrangement direction and a thickness direction of the second conductor extend in the arrangement direction and which are electrically connected to the plurality of semiconductor elements, with respect to the plurality of semiconductor elements.

According to the aspect, it is possible to disperse heat generation due to current flow in a semiconductor device including a plurality of semiconductor elements located side by side in a row.

### BRIEF DESCRIPTION OF DRAWINGS

FIG. 1 is a plan view illustrating the schematic configuration of a semiconductor device according to a first embodiment;

FIG. 2 is a plan view illustrating the schematic configuration of a unit module in the first embodiment;

FIG. 3 is a plan view illustrating the schematic configuration of a unit module in a second embodiment;

FIG. 4 is a plan view illustrating the schematic configuration of a unit module in a third embodiment;

FIG. 5 is a plan view illustrating the schematic configuration of a unit module in a fourth embodiment;

FIG. 6 is a plan view illustrating the schematic configuration of a unit module in a fifth embodiment; and

FIG. 7 is a plan view illustrating the schematic configuration of a unit module in a sixth embodiment.

### DETAILED DESCRIPTION

Hereinafter, semiconductor devices according to first to sixth embodiments of the present invention will be described with reference to the drawings. In addition, the present invention is not limited to the embodiments described below, and can be appropriately modified and implemented within the scope not changing the gist thereof.

### First Embodiment

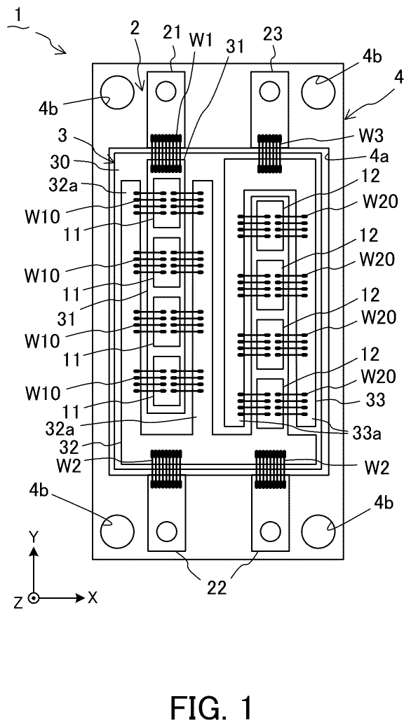

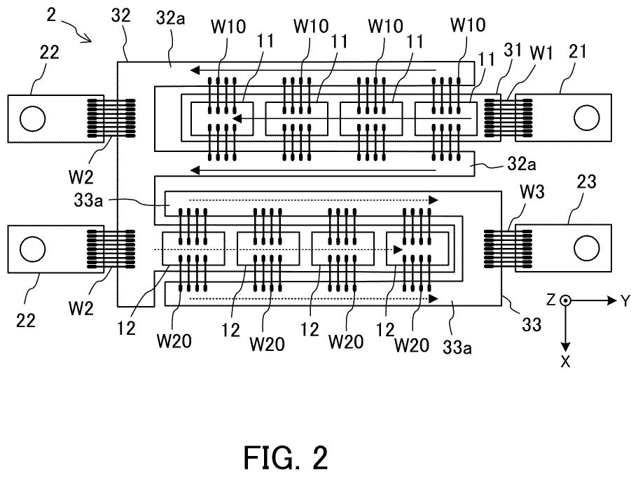

FIG. 1 is a plan view illustrating a semiconductor device 1 according to the first embodiment. In addition, FIG. 2 is a plan view illustrating the schematic configuration of a unit module 2 in the first embodiment.

In FIGS. 1 and 2 and FIGS. 3 to 7 to be described later, a height direction (thickness direction of the substrate) of the semiconductor device 1 is defined as a Z direction, a longitudinal direction of the semiconductor device 1 between the X and Y directions perpendicular to the Z direction is defined as a Y direction, and a lateral direction of the semiconductor device 1 is defined as an X direction. Unlike the example of FIG. 1, when a plurality of semiconductor modules (unit modules 2) are arranged side by side in the X direction, the longitudinal direction of the semiconductor device 1 is the X direction. The illustrated X, Y, and Z axes are perpendicular to each other and form a right-handed system. In some cases, as will be described later, the X direction may be referred to as a width direction, the Y direction may be referred to as an arrangement direction, and the Z direction may be referred to as a vertical direction. For example, a heat dissipation surface side (cooler side) of the semiconductor device 1 is referred to as a lower surface side, and the opposite side thereof is referred to as an upper surface side. These directions are terms used for convenience of description, and the correspondence relationship with each of the XYZ directions may change depending on the attachment posture of the semiconductor device 1. In this specification, the term “in plan view” means a case where the upper surface of the semiconductor device is viewed from the Z direction.

The semiconductor device 1 according to the present embodiment is applied to, for example, a power converter such as a power control unit, and is a power semiconductor module forming an inverter circuit.

As illustrated in FIG. 1, the semiconductor device 1 includes a unit module 2, a cooler (not illustrated) for cooling the unit module 2, a case member 4 in which the unit module 2 is housed, and a sealing resin (not illustrated) injected into the case member 4.

The unit module 2 includes a circuit board 3 and a plurality of semiconductor elements (a first semiconductor element 11 and a second semiconductor element 12) arranged on the circuit board 3. Three unit modules 2 may be arranged side by side in the X direction. In this case, the three unit modules 2 form, for example, a U phase, a V phase, and a W phase, and form a three-phase inverter circuit as a whole. The unit module 2 may be referred to as a power cell or a semiconductor unit. The unit module 2 may be arranged in any number of one or more.

The circuit board 3 is, for example, a direct copper bonding (DCB) substrate, an active metal brazing (AMB) substrate, or a metal base substrate. For example, the circuit board 3 includes an insulating plate 30, a heat dissipation plate (not illustrated) arranged on the lower surface of the insulating plate 30, and conductors (a first conductor 31, a second conductor 32, and a third conductor 33) arranged on the upper surface of the insulating plate 30. The circuit board 3 is formed in, for example, a rectangular shape in plan view. In FIG. 2, illustration of the insulating plate 30 is omitted.

For example, the insulating plate 30 is formed of an insulating material, such as a ceramic material such as alumina (Al₂O₃) aluminum nitride (AlN), or silicon nitride (Si₃N₄), a resin material such as epoxy, or an epoxy resin material using a ceramic material as a filler. In addition, the insulating plate 30 may be referred to as an insulating layer or an insulating film.

A heat dissipation plate (not illustrated) arranged on the lower surface of the insulating plate 30 has a predetermined thickness in the Z direction, and is formed to cover the lower surface of the insulating plate 30. For example, the heat dissipation plate is formed of a metal plate having good thermal conductivity, such as copper or aluminum.

The case member 4 is bonded to a base plate (for example, the heat dissipation plate described above) of a cooler (not illustrated) through, for example, an adhesive. The case member 4 is formed in a rectangular frame shape having an opening 4a at the center. The unit module 2 is housed in the rectangular opening 4a. That is, the unit module 2 is housed in a space defined by the frame-shaped case member 4.

In the case member 4, a first terminal 21 functioning as a P terminal, for example, two second terminals 22 functioning as M terminals, and a third terminal 23 functioning as an N terminal are arranged as main terminals for external connection of the unit module 2. The first terminal 21 and the third terminal 23 and the two second terminals 22 are located so as to face each other in the Y direction with the opening 4a interposed therebetween. The number of second terminals 22 may be one, or is not limited.

The first terminal 21 (P terminal) can be referred to as a positive electrode terminal (input terminal), the second terminal 22 (M terminal) can be referred to as an intermediate terminal (output terminal), and the third terminal 23 (N terminal) can be referred to as a negative electrode terminal (output terminal). In FIG. 2, an upper layer current flowing from the first terminal 21 to the two second terminals 22 through the first conductor 31, the plurality of first semiconductor elements 11, and the second conductor 32 (shoulder portion and two first divided pieces (first and second extended portions) 32a disposed spaced apart from each other in the X direction) is indicated by a solid arrow. A lower layer current flowing from the two second terminals 22 to the third terminal 23 through the second conductor 32, the plurality of second semiconductor elements 12, and the third conductor 33 (two second divided pieces (two extended portions) 33a) is indicated by a broken line arrow.

As illustrated in FIG. 1, a plurality of through holes 4b are formed along the outer peripheral edge of the case member 4. These through holes 4b are holes for inserting screws (not illustrated) for fixing the semiconductor device 1. The through hole 4b penetrates up to the base plate of the cooler.

The resin for the case member 4 can be selected from, for example, polyphenylene sulfide (PPS), polybutylene terephthalate (PBT), polybutyl acrylate (PBA), polyamide (PA), acrylonitrile butadiene styrene (ABS), liquid crystal polymer (LCP), polyether ether ketone (PEEK), polybutylene succinate (PBS), and insulating resins such as urethane and silicon. The selected resin may be a mixture of two or more kinds of resins. The resin may contain a filler (for example, a glass filler) for improving strength or functionality.

An internal space defined by the frame-shaped case member 4 is filled with a sealing resin (not illustrated). That is, the circuit board 3 and the first semiconductor element 11 and the second semiconductor element 12 illustrated in FIG. 2, which are mounted on the circuit board 3, are sealed in the above space. The case member 4 defines a space for housing the plurality of unit modules 2 and the sealing resin.

The sealing resin is a thermosetting resin. Preferably, the sealing resin contains at least one of epoxy, silicone, urethane, polyimide, polyamide, and polyamide-imide. As the sealing resin, for example, an epoxy resin containing a filler is preferable in terms of its insulation, heat resistance, and heat dissipation.

As illustrated in FIG. 2, the plurality of (for example, 4) first semiconductor elements 11 are located side by side in a row in the Y direction. The plurality of (for example, 4) second semiconductor elements 12 are located side by side in a row in the Y direction at intervals on the positive side in the X direction with respect to the first semiconductor element 11. The first semiconductor element 11 and the second semiconductor element 12 are, for example, RC-IGBT elements.

Although the shapes, the number of arrangements, the arrangement places, and the like of the first semiconductor element 11 and the second semiconductor element 12 can be appropriately changed, the first semiconductor element 11 and the second semiconductor element 12 have a rectangular shape elongated in the arrangement direction (Y direction) in plan view. The first semiconductor element 11 and the second semiconductor element 12 are each formed in a rectangular shape or a square shape in planar view by using a semiconductor substrate formed of silicon (Si), silicon carbide (SiC), gallium nitride (GaN), diamond, and the like, for example.

As illustrated in FIG. 2, the first terminal 21 is connected to the first conductor 31 by a wiring member W1, the two second terminals 22 are connected to the second conductor 32 by a wiring member W2, and the third terminal 23 is connected to the third conductor 33 by a wiring member W3. For these wiring members W1 to W3 and wiring members W10 and W20 to be described later, for example, a plurality of conductor wires (bonding wires) are used. As a material of the conductive wire, any one of gold, copper, aluminum, a gold alloy, a copper alloy, and an aluminum alloy or any combination thereof can be used. As the wiring member, a member other than the conductive wire can be used. For example, a metal wiring board (lead frame) formed by bending by press working or the like, a ribbon, and the like can be used as the wiring member.

The first conductor 31, the second conductor 32, and the third conductor 33 are, for example, metal layers such as copper foil, and are formed in an island shape so as to be electrically insulated from each other on the insulating plate 30 illustrated in FIG. 1. The first conductor 31, the second conductor 32, and the third conductor 33 may be referred to as a circuit plate or a circuit layer.

The first conductor 31 has a rectangular shape in plan view having a longitudinal direction in the Y direction that is the arrangement direction of the first semiconductor elements 11. The plurality of first semiconductor elements 11 are arranged on the upper surface of the first conductor 31 with a bonding material such as solder (not illustrated) interposed therebetween. In this manner, the first conductor 31 electrically connects the first terminal 21 connected by the wiring member W1 and the plurality of first semiconductor elements 11 to each other.

The second conductor 32 has an approximately E shape in plan view. In the second conductor 32, from a portion extending in the X direction and connected to the two second terminals 22 by the wiring member W2, a total of three portions including a portion (third extended portion) where the plurality of second semiconductor elements 12 are arranged and two first divided pieces 32a to be described later extend to the positive side in the Y direction. The plurality of second semiconductor elements 12 are arranged on the upper surface of the second conductor 32 with a bonding material such as solder (not illustrated) interposed therebetween.

The second conductor 32 has the two first divided pieces 32a that extend in the arrangement direction (Y direction) on both sides in the width direction (X direction) perpendicular to the arrangement direction (Y direction) and the thickness direction (Z direction) of the second conductor 32 with respect to the plurality of first semiconductor elements 11 and that are electrically connected to the plurality of first semiconductor elements 11 by the wiring member W10. In this manner, the second conductor 32 electrically connects the two second terminals 22 connected by the wiring member W2 and the plurality of first semiconductor elements 11 to each other. As described above, since the plurality of second semiconductor elements 12 are arranged in the second conductor 32, the two second terminals 22 and the plurality of second semiconductor elements 12 are electrically connected to each other. When the first semiconductor element 11 is an RC-IGBT element, the active area is large, so that it is easy to connect a sufficient number of wiring members W10 for connection with each of the two first divided pieces 32a.

The third conductor 33 has approximately U shape in plan view, and two second divided pieces 33a to be described later extend to the negative side in the Y direction from a portion extending in the X direction and connected to the third terminal 23 by the wiring member W3.

The third conductor 33 has two second divided pieces 33a that extend in the arrangement direction (Y direction) on both sides in the width direction (X direction) with respect to the plurality of second semiconductor elements 12 and are electrically connected to the plurality of second semiconductor elements 12 by the wiring member W20. In this manner, the third conductor 33 electrically connects the third terminal 23 connected by the wiring member W3 and the plurality of second semiconductor elements 12 to each other.

In the above-described unit module 2, it can be said that the first terminal 21 is located on one side (positive side in the Y direction) in the arrangement direction of the plurality of first semiconductor elements 11 with respect to the plurality of first semiconductor elements 11, the first conductor 31, and the second conductor 32. In addition, it can be said that the two second terminals 22 are located on the other side (negative side in the Y direction) in the arrangement direction of the plurality of first semiconductor elements 11 with respect to the plurality of first semiconductor elements 11, the first conductor 31, and the second conductor 32.

In addition, it can be said that the third terminal 23 is located on one side (positive side in the Y direction) in the arrangement direction with respect to the plurality of second semiconductor elements 12, the second conductor 32, and the third conductor 33.

In the first embodiment described above, the semiconductor device 1 includes the first semiconductor element 11 that is an example of a plurality of semiconductor elements located side by side in a row, the first terminal 21 and, for example, the two second terminals 22, the first conductor 31 electrically connecting the first terminal 21 and the plurality of first semiconductor elements 11 to each other, and the second conductor 32 electrically connecting the plurality of first semiconductor elements 11 and the second terminal 22 to each other. The first terminal 21 is located on one side (positive side in the Y direction) in the arrangement direction of the plurality of first semiconductor elements 11 with respect to the plurality of first semiconductor elements 11, the first conductor 31, and the second conductor 32. The two second terminals 22 are located on the other side (negative side in the Y direction) in the arrangement direction with respect to the plurality of first semiconductor elements 11, the first conductor 31, and the second conductor 32. The second conductor 32 has two first divided pieces 32a, which are an example of two divided pieces whose both sides extend in the arrangement direction (Y direction) on both sides in the width direction (X direction) perpendicular to the arrangement direction (Y direction) and the thickness direction (Z direction) of the second conductor 32 and which are electrically connected to the plurality of first semiconductor elements 11, with respect to the plurality of first semiconductor elements 11.

As a result, the current flowing from the first terminal 21 to the second conductor 32 through the first conductor 31 and the plurality of first semiconductor elements 11 is distributed to the two first divided pieces 32a located on both sides in the width direction (X direction) with the plurality of first semiconductor elements 11 interposed therebetween. For this reason, it is possible to suppress the occurrence of warpage in a heat dissipation plate or the like arranged below the second conductor 32 (circuit board 3). Therefore, it is possible to suppress the generation of a gap between the heat dissipation plate and the cooler (heat sink) arranged below the heat dissipation plate, and it is also possible to prevent heat generation from being concentrated by the gap. As a result, according to the first embodiment, in the semiconductor device 1 including the plurality of semiconductor elements (first semiconductor elements 11) located side by side in a row, heat generation due to current flow can be dispersed. In addition, the output current can be increased accordingly.

In addition, in the first embodiment, the semiconductor device 1 further includes a plurality of second semiconductor elements 12 located side by side in a row in parallel with the plurality of first semiconductor elements 11, a third terminal 23, and a third conductor 33 electrically connecting the plurality of second semiconductor elements 12 and the third terminal 23 to each other. The third terminal 23 is located on one side (positive side in the Y direction) in the arrangement direction with respect to the plurality of second semiconductor elements 12, the second conductor 32, and the third conductor 33. The second conductor 32 electrically connects the plurality of first semiconductor elements 11 and the second terminal 22 to each other, and electrically connects the second terminal 22 and the plurality of second semiconductor elements 12 to each other. The third conductor 33 has two second divided pieces 33a, of which both sides in the width direction (X direction) extend in the arrangement direction (Y direction) and which are electrically connected to the plurality of second semiconductor elements 12, with respect to the plurality of second semiconductor elements 12.

Therefore, the current flowing from the second terminal 22 to the third terminal 23 through the plurality of second semiconductor elements 12 located side by side in a row in parallel with the plurality of first semiconductor elements 11 is distributed to the two second divided pieces 33a located on both sides in the width direction (X direction) with the plurality of second semiconductor elements 12 interposed therebetween. As a result, it is possible to further disperse heat generated due to current flow.

### Second Embodiment

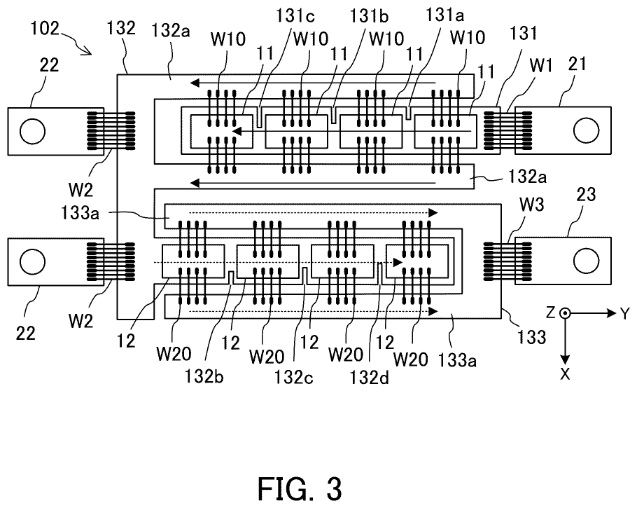

FIG. 3 is a plan view showing the schematic configuration of a unit module 102 in a second embodiment.

The unit module 102 illustrated in FIG. 3 can be similar to the unit module 2 in the first embodiment illustrated in FIG. 2 except that the first conductor 131 has notches 131a to 131c and the second conductor 132 has notches 132b to 132d. Therefore, detailed description will be omitted.

The first conductor 131 has a plurality of notches 131a, 131b, and 131c arranged such that the notched area increases toward the downstream side (negative side in the Y direction) of the current. These notches 131a to 131c are located between the plurality of first semiconductor elements 11, and are notched in a rectangular shape, for example. The lengths of the notches 131a to 131c in the Y direction are, for example, the same.

For example, the notch 131a between the first semiconductor element 11 located at the end on the upstream side of the current (positive side in the Y direction), among the plurality of first semiconductor elements 11, and the second first semiconductor element 11 adjacent to the first first semiconductor element 11 has the smallest length in the X direction among the notches 131a to 131c. In addition, the notch 131b between the second first semiconductor element 11 and the third first semiconductor element 11 adjacent to the second first semiconductor element 11 has a larger length in the X direction than the notch 131a. In addition, the notch 131c between the third first semiconductor element 11 and the fourth first semiconductor element 11 adjacent to the third first semiconductor element 11 has a larger length in the X direction than the notch 131b. In this manner, the plurality of notches 131a, 131b, and 131c are arranged such that the notch area increases toward the downstream side (negative side in the Y direction) of the current.

Notches 132b, 132c, and 132d are provided between the plurality of second semiconductor elements 12 in the second conductor 132. These notches 132b to 132d are arranged such that the notch area increases toward the downstream side (positive side in the Y direction) of the current of the second conductor 132.

The notch areas of the notches 131a to 131c of the first conductor 131 and the notches 132b to 132d of the second conductor 132 may be increased in at least one step toward the downstream side of the current. In addition, the notches 131a to 131c and 132b to 132d may have different areas, for example, due to the same length in the X direction and different lengths in the Y direction or due to different lengths in both the X direction and the Y direction. In addition, a plurality of notches 131a to 131c and a plurality of notches 132b to 132d may be provided between the plurality of first semiconductor elements 11 or the plurality of second semiconductor elements 12, respectively.

Although the notches 131a to 131c and 132b to 132d are provided only at the end on one side in the X direction in the portion where the plurality of second semiconductor elements 12 of the first conductor 131 or the second conductor 132 are arranged, the notches 131a to 131c and 132b to 132d may be provided only at the end on the other side in the X direction in the portion where the plurality of second semiconductor elements 12 of the first conductor 131 or the second conductor 132 are arranged, or may be provided at both ends in the X direction in the first conductor 131 or the second conductor 132.

In the second embodiment described above, regarding the same matters as in the first embodiment described above, it is possible to obtain the same effect, that is, the effect of being able to disperse the heat generation due to current flow.

In the second embodiment, the first conductor 131 has a plurality of notches 131a, 131b, and 131c arranged such that the notched area increases toward the downstream side of the current. The plurality of notches 131a to 131c are located, for example, between the plurality of first semiconductor elements 11.

Therefore, for example, variations in the electric resistance value of the current path flowing from the first semiconductor element 11 on the upstream side of the current to the second terminal 22 through the two first divided pieces 132a and the electric resistance value of the current path flowing from the first semiconductor element 11 on the downstream side of the current to the second terminal 22 through the two first divided pieces 132a can be suppressed by the notches 131a to 131c. That is, by averaging the electric resistance values for each current path, it is possible to eliminate the current imbalance between the current path flowing from the first semiconductor element 11 on the upstream side of the current to the second terminal 22 through the two first divided pieces 132a and the current path flowing from the first semiconductor element 11 on the downstream side of the current to the second terminal 22 through the two first divided pieces 132a. In addition, by providing the notches 131a to 131c, it is possible to suppress bonding materials such as solder located below the first semiconductor element 11 from being bonded and interfering with each other between the adjacent first semiconductor elements 11. As a result, it is also possible to suppress positional displacement of the first semiconductor element 11 and variations in heat distribution due to the positional displacement. These effects can be similarly obtained for the notches 132b to 132d provided in the second conductor 132.

### Third Embodiment

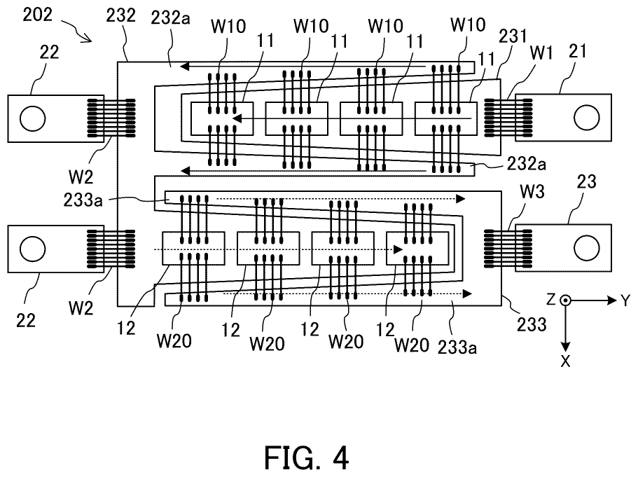

FIG. 4 is a plan view showing the schematic configuration of a unit module 202 in a third embodiment.

A unit module 202 illustrated in FIG. 4 can be similar to the unit module 2 in the first embodiment illustrated in FIG. 2 except for the widths of the first conductor 231, the second conductor 232, and the third conductor 233 in the width direction (X direction). Therefore, detailed description will be omitted.

The width of the first conductor 231 in the width direction (X direction) decreases toward the downstream side (negative side in the Y direction) of the current. On the other hand, the widths of the two first divided pieces 232a of the second conductor 232 in the width direction (X direction) increase toward the downstream side (negative side in the Y direction) of the current.

Similarly, a portion of the second conductor 232 where the plurality of second semiconductor elements 12 are arranged has a width in the width direction (X direction) that decreases toward the downstream side (positive side in the Y direction) of the current. On the other hand, the widths of the two second divided pieces 233a of the third conductor 233 in the width direction (X direction) increase toward the downstream side (positive side in the Y direction) of the current.

The width may change toward the downstream side of the current only in portions of the first conductor 231 and the second conductor 232 where the plurality of second semiconductor elements 12 are arranged.

In addition, it is desirable that the width change gradually decreases or gradually increases continuously toward the downstream side of the current, but the width change may gradually decrease or gradually increase intermittently. In addition, the notches 131a, 131b, 131c, 132b, 132c, and 132d illustrated in FIG. 3 described above may be provided in at least one of the first conductor 231 and the portion of the second conductor 232 where the second semiconductor element 12 is arranged.

In the third embodiment described above, regarding the same matters as in the first embodiment described above, it is possible to obtain the same effect, that is, the effect of being able to disperse the heat generation due to current flow.

In the third embodiment, the width of the first conductor 231 in the width direction (X direction) decreases toward the downstream side (negative side in the Y direction) of the current.

Therefore, for example, variations in the electric resistance value of the current path flowing from the first semiconductor element 11 on the upstream side of the current to the second terminal 22 through the two first divided pieces 232a and the electric resistance value of the current path flowing from the first semiconductor element 11 on the downstream side of the current to the second terminal 22 through the two first divided pieces 232a can be suppressed. That is, by averaging the electric resistance values for each current path, it is possible to eliminate the current imbalance between the current path flowing from the first semiconductor element 11 on the upstream side of the current to the second terminal 22 through the two first divided pieces 232a and the current path flowing from the first semiconductor element 11 on the downstream side of the current to the second terminal 22 through the two first divided pieces 232a. This effect can be similarly obtained with respect to the fact that the portion of the second conductor 232 where the second semiconductor element 12 is arranged narrows in the width direction (X direction) toward the downstream side (positive side in the Y direction) of the current. In addition, since the widths of the two first divided pieces 232a in the width direction (X direction) increase toward the downstream side (negative side in the Y direction) of the current, the current resistance of each portion with respect to the current can be adjusted using not only the width of the first conductor 231 but also the widths of the two first divided pieces 232a. Therefore, the imbalance of the current for each current path can be further eliminated. In addition, since the widths of the two first divided pieces 232a can be increased by using the region where the width of the first conductor 231 decreases, the unit module 202 can be made small.

### Fourth Embodiment

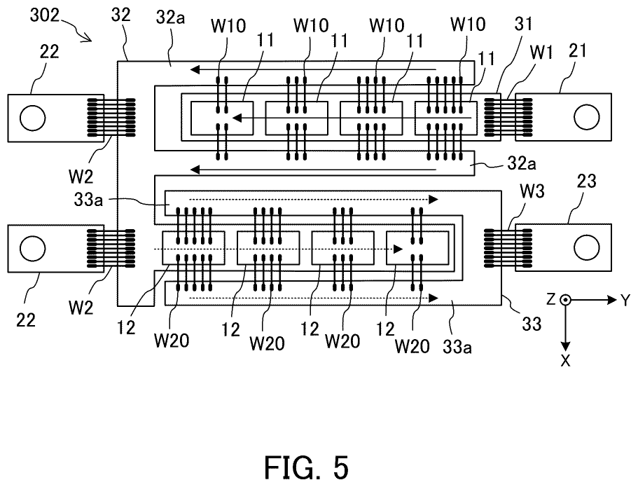

FIG. 5 is a plan view showing the schematic configuration of a unit module 302 in a fourth embodiment.

The unit module 302 illustrated in FIG. 5 can be similar to the unit module 2 in the first embodiment illustrated in FIG. 2 except for the number of wiring members W10 connecting the plurality of first semiconductor elements 11 and the first divided piece 32a of the second conductor 32 to each other and the number of wiring members W20 connecting the plurality of second semiconductor elements 12 and the second divided piece 33a of the third conductor 33 to each other. Therefore, detailed description will be omitted.

The first semiconductor element 11 connected to the downstream side (negative side in the Y direction) of the current in the two first divided pieces 32a of the second conductor 32 is connected to the two first divided pieces 32a by a smaller number of wiring members W10 than the first semiconductor element 11 connected to the upstream side (positive side in the Y direction) of the current in the two first divided pieces 32a.

For example, among the plurality of first semiconductor elements 11, the first first semiconductor element 11 located at the end on the downstream side of the current is connected to each of the two first divided pieces 32a by the two wiring members W10. The second first semiconductor element 11 adjacent to the first first semiconductor element 11 is connected to each of the two first divided pieces 32a by the three wiring members W10. The third first semiconductor element 11 adjacent to the second first semiconductor element 11 is connected to each of the two first divided pieces 32a by the four wiring members W10. The fourth first semiconductor element 11 adjacent to the third first semiconductor element 11 is connected to each of the two first divided pieces 32a by the five wiring members W10.

Among the plurality of second semiconductor elements 12, the first second semiconductor element 12 located at the end on the downstream side (positive side in the Y direction) of the current is connected to each of the two second divided pieces 33a by the two wiring members W20. The second second semiconductor element 12 adjacent to the first second semiconductor element 12 is connected to each of the two second divided pieces 33a by the three wiring members W20. The third second semiconductor element 12 adjacent to the second second semiconductor element 12 is connected to each of the two second divided pieces 33a by the four wiring members W20. The fourth second semiconductor element 12 adjacent to the third second semiconductor element 12 is connected to each of the two second divided pieces 33a by the five wiring members W20.

The number of wiring members W10 and W20 may be reduced in at least one step toward the downstream side of the current. In addition, instead of or together with the number of wiring members W10 and W20, the cross-sectional area (area of the cross section perpendicular to the current path) of the wiring members W10 and W20 may be reduced in at least one step toward the downstream side of the current. Changing the number of wiring members W10 and W20 as in the fourth embodiment may be applied to the unit module 102 illustrated in FIG. 3 of the second embodiment described above or the unit module 202 illustrated in FIG. 4 of the third embodiment described above.

In the fourth embodiment described above, regarding the same matters as in the first embodiment described above, it is possible to obtain the same effect, that is, the effect of being able to disperse the heat generation due to current flow.

In addition, in the fourth embodiment, the semiconductor device 1 further includes a plurality of wiring members W10 electrically connecting the plurality of first semiconductor elements 11 and the two first divided pieces 32a to each other. The plurality of first semiconductor elements 11 are connected to the two first divided pieces 32a by a smaller number of wiring members W10 in the case of the first semiconductor element 11 connected to the downstream side of the current in the two first divided pieces 32a than in the case of the first semiconductor element 11 connected to the upstream side of the current in the two first divided pieces 32a.

Therefore, for example, variations in the electric resistance value of the current path flowing from the first semiconductor element 11 on the upstream side of the current to the second terminal 22 through the two first divided pieces 32a and the electric resistance value of the current path flowing from the first semiconductor element 11 on the downstream side of the current to the second terminal 22 through the two first divided pieces 32a can be suppressed. That is, by averaging the electric resistance values for each current path, it is possible to eliminate the current imbalance between the current path flowing from the first semiconductor element 11 on the upstream side of the current to the second terminal 22 through the two first divided pieces 32a and the current path flowing from the first semiconductor element 11 on the downstream side of the current to the second terminal 22 through the two first divided pieces 32a. This effect can be similarly obtained for the number of wiring members W20 connecting the second semiconductor element 12 and the two second divided pieces 33a to each other.

### Fifth Embodiment

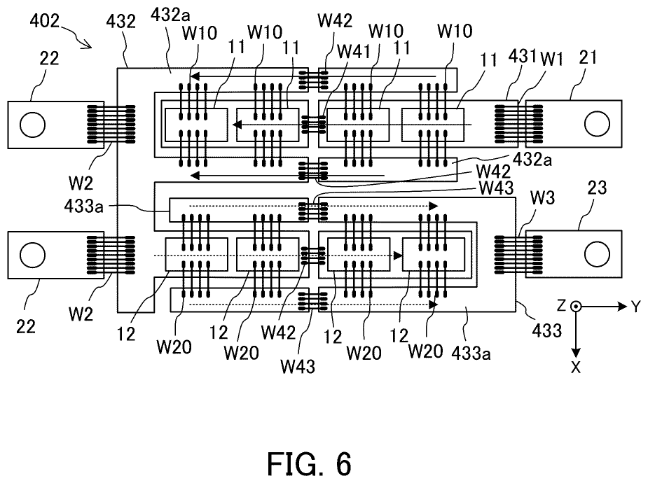

FIG. 6 is a plan view showing the schematic configuration of a unit module 402 in a fifth embodiment.

The unit module 402 illustrated in FIG. 6 can be similar to the unit module 2 in the first embodiment illustrated in FIG. 2 except that each of the first conductor 431, the second conductor 432, and the third conductor 433 is separated into two portions in the middle of the arrangement direction (Y direction). Therefore, detailed description will be omitted.

The first conductors 431 are separated into two portions in the middle of the arrangement direction (Y direction) (between the first terminal 21 and the second terminal 22) so that the first semiconductor elements 11 are located separately. Both the separated portions of the first conductor 431 are electrically connected to each other by a wiring member W41.

The second conductor 432 is separated into two portions in the middle of the arrangement direction (Y direction) at three locations of two first divided pieces 432a and a portion where the plurality of second semiconductor elements 12 are arranged. Both the separated portions of the second conductor 432 are electrically connected to each other by a wiring member W42.

The third conductor 433 is separated into two portions in the middle of the arrangement direction (Y direction) in each of the two second divided pieces 433a. Both the separated portions of the third conductor 433 are electrically connected to each other by a wiring member W43.

Each of the first conductor 431, the second conductor 432, and the third conductor 433 is separated into two portions at the same position in the arrangement direction (Y direction), but the separation positions may be different from each other. At least one portion of at least one of the first conductor 431, the second conductor 432, and the third conductor 433 may be separated into two portions, or the separation portion is any separation portion. In addition, each of the first conductor 431, the second conductor 432, and the third conductor 433 may be separated into three or more portions in the middle of the arrangement direction (Y direction), and the separated three or more portions may be electrically connected to each other by the wiring members W41, W42, and W43.

Separating each of the first conductor 431, the second conductor 432, and the third conductor 433 into two portions as in the fifth embodiment may be applied to the unit module 102 illustrated in FIG. 3 of the second embodiment described above, the unit module 202 illustrated in FIG. 4 of the third embodiment described above, and the unit module 302 illustrated in FIG. 5 of the fourth embodiment described above.

In the fifth embodiment described above, regarding the same matters as in the first embodiment described above, it is possible to obtain the same effect, that is, the effect of being able to disperse the heat generation due to current flow.

In the fifth embodiment, the two first divided pieces 32a of the first conductor 431 and the second conductor 432 are separated into two portions between the first terminal 21 and the second terminal 22, and both the separated portions are electrically connected to each other by the wiring members W41 and W42. In the two second divided pieces 433a of the third conductor 433 and the portion of the second conductor 432 where the plurality of second semiconductor elements 12 are arranged are separated into two portions between the second terminal 22 and the third terminal 23, and both the separated portions are electrically connected to each other by the wiring members W42 and W43.

Therefore, for example, the first conductor 431, the second conductor 432, and the third conductor 433 can be prevented from being broken due to warping of the unit module 402 when the case member 4 is fastened to the cooler in the through hole 4b.

### Sixth Embodiment

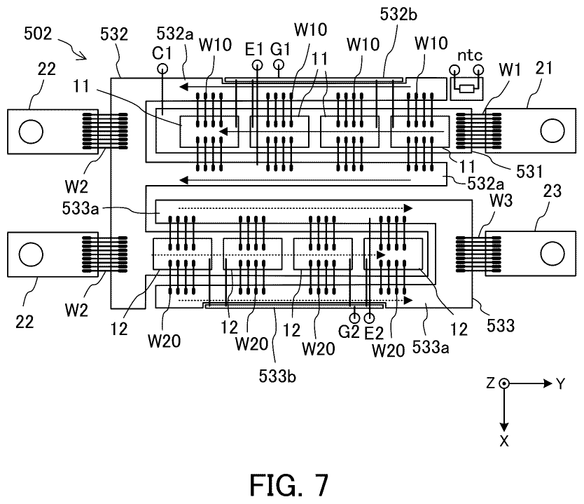

A unit module 502 illustrated in FIG. 7 can be similar to the unit module 2 in the first embodiment illustrated in FIG. 2, except that gate wiring circuit boards 532b and 533b are mainly arranged. Therefore, detailed description will be omitted.

An end on the negative side in the X direction of one (negative side in the X direction) first divided piece 532a of the second conductor 532 is cut out to secure a region where the gate wiring circuit board 532b long in the Y direction is arranged. In addition, an end on the positive side in the X direction of one (positive side in the X direction) second divided piece 533a of the third conductor 533 is cut out to secure a region where the gate wiring circuit board 533b long in the Y direction is arranged.

The gate wiring circuit board 532b forms a first control wiring member that electrically connects the gate electrode of each of the plurality of first semiconductor elements 11 and a pad portion G1 of an external connection terminal for gate signal input. The gate wiring circuit board 533b forms a second control wiring member that electrically connects the gate electrode of each of the plurality of second semiconductor elements 12 and a pad portion G2 of the external connection terminal for gate signal input.

As illustrated in FIG. 7, the end on the negative side in the Y direction of the first conductor 531 is directly connected to a pad portion C1 for external connection to which the collector electrode is connected by the wiring member, and the first divided piece 532a and the second divided piece 533a are directly connected to pad portions E1 and E2 for external connection to which the emitter electrode is connected by the wiring member. On the positive side in the Y direction of the one (negative side in the X direction) first divided piece 532a of the second conductor 532, a thermistor (ntc (negative temperature coefficient) thermistor) is arranged at a position separated from the first divided piece 532a.

In the sixth embodiment described above, regarding the same matters as in the first embodiment described above, it is possible to obtain the same effect, that is, the effect of being able to disperse the heat generation due to current flow. In addition, the plurality of first semiconductor elements 11 and the plurality of second semiconductor elements 12 are located side by side in a row, and only one first divided piece 532a or second divided piece 533a of the conductors is located outside the first semiconductor element 11 and the second semiconductor element 12 in the lateral direction (X direction) of the unit module 502. For this reason, it is easy to directly wire each portion, such as a semiconductor element or a conductor of the unit module 502, and the pad portions C1, E1, E2, G1, and G2 without interposing a conductor for the pad portion. Therefore, the wiring length can be shortened to have a simple configuration, and the measurement accuracy and the like can be improved.

Hereinafter, the invention described in the claims of the originally filed application will be additionally described.

### Supplementary Note 1

A semiconductor device, including:

a plurality of semiconductor elements located side by side in a row;

a first terminal and a second terminal;

a first conductor electrically connecting the first terminal and the plurality of semiconductor elements to each other; and

a second conductor electrically connecting the plurality of semiconductor elements and the second terminal to each other,

wherein the first terminal is located on one side in an arrangement direction of the plurality of semiconductor elements with respect to the plurality of semiconductor elements, the first conductor, and the second conductor,

the second terminal is located on the other side in the arrangement direction with respect to the plurality of semiconductor elements, the first conductor, and the second conductor, and

the second conductor has two divided pieces, of which both sides in a width direction perpendicular to the arrangement direction and a thickness direction of the second conductor extend in the arrangement direction and which are electrically connected to the plurality of semiconductor elements, with respect to the plurality of semiconductor elements.

### Supplementary Note 2

The semiconductor device according to Supplementary Note 1,

wherein the first conductor has a plurality of notches arranged such that a notched area increases toward a downstream side of a current.

### Supplementary Note 3

The semiconductor device according to Supplementary Note 2,

wherein the plurality of notches are located between the plurality of semiconductor elements.

### Supplementary Note 4

The semiconductor device according to Supplementary Note 1,

wherein a width of the first conductor in the width direction decreases toward a downstream side of a current.

### Supplementary Note 5

The semiconductor device according to Supplementary Note 1, further including:

a plurality of wiring members that electrically connect the plurality of semiconductor elements and the two divided pieces to each other,

wherein the plurality of semiconductor elements are connected to the two divided pieces by a smaller number of the wiring members in a case of a semiconductor element connected to a downstream side of a current in the two divided pieces than in a case of a semiconductor element connected to an upstream side of the current in the two divided pieces.

### Supplementary Note 6

The semiconductor device according to Supplementary Note 1,

wherein the first conductor and the two divided pieces are separated into two portions between the first terminal and the second terminal, and both the separated portions are electrically connected to each other by a wiring member.

### Supplementary Note 7

The semiconductor device according to Supplementary Note 1,

wherein the plurality of semiconductor elements located side by side in a row are a plurality of first semiconductor elements,

the two divided pieces of the second conductor are two first divided pieces,

the semiconductor device further includes

a plurality of second semiconductor elements located side by side in a row in parallel with the plurality of first semiconductor elements,

a third terminal, and

a third conductor electrically connecting the plurality of second semiconductor elements and the third terminal to each other,

the third terminal is located on one side in the arrangement direction with respect to the plurality of second semiconductor elements, the second conductor, and the third conductor,

the second conductor electrically connects the plurality of first semiconductor elements and the second terminal to each other and electrically connects the second terminal and the plurality of second semiconductor elements to each other, and

the third conductor has two second divided pieces, of which both sides in the width direction extend in the arrangement direction and which are electrically connected to the plurality of second semiconductor elements, with respect to the plurality of second semiconductor elements.

As described above, the present invention has an effect of being able to disperse heat generated due to current flow in a semiconductor device including a plurality of semiconductor elements located side by side in a row, and is useful for, for example, a power semiconductor device.

This application is based on Japanese Patent Application No. 2022-135711 filed on Aug. 29, 2022. All the contents are included herein.

What is claimed is:

1. A semiconductor device, comprising:
a first terminal and a second terminal;
a first conductor having a plurality of semiconductor elements arranged side by side in an arrangement direction thereon, the first conductor electrically connecting the plurality of semiconductor elements to the first terminal via first wiring; and
a second conductor electrically connecting the plurality of semiconductor elements on the first conductor to the second terminal via second wiring, wherein
the first terminal is located on one side of the first conductor in the arrangement direction,
the second terminal is located on one side of the second conductor in the arrangement direction, another side of the second conductor opposite to the one side of the second conductor being located at the same side of the first conductor as the one side of the first conductor with respect to the arrangement direction, and
the second conductor has a shoulder portion that extends in a width direction perpendicular to both the arrangement direction and a thickness direction of the second conductor, and two extended portions arranged at the shoulder portion spaced apart from each other in the width direction, the two extended portions both extending in the arrangement direction and being electrically connected to the plurality of semiconductor elements.

2. The semiconductor device according to claim 1,
wherein the first conductor has a plurality of notches arranged such that a size of a notched increases toward a downstream side of a current passing through the first conductor.

3. The semiconductor device according to claim 2,
wherein each of the plurality of notches is located between a corresponding two of the plurality of semiconductor elements that are adjacent to each other.

4. The semiconductor device according to claim 1,
wherein a width of the first conductor in the width direction decreases toward a downstream side of a current passing through the first conductor.

5. The semiconductor device according to claim 1, wherein
the second wiring includes a plurality of wiring members that respectively electrically connect a respective one of the plurality of semiconductor elements to either one of the two extended portions, and
a total number of wiring members of the plurality of wiring members that connect a respective one of the plurality of semiconductor elements to either one of the two extended portions decreases toward a downstream side of a current passing through the first conductor.

6. The semiconductor device according to claim 1,
wherein the first conductor and the two extended portions each are separated into two portions to have a gap in the arrangement direction, the two portions of each of the first conductor and the two extended portions being electrically connected to each other by wiring.

7. The semiconductor device according to claim 1, wherein
the plurality of semiconductor elements on the first conductor is a plurality of first semiconductor elements,
the two extended portions of the second conductor are a first extended portion and a second extended portion, and
the second conductor further includes a third extended portion having a plurality of second semiconductor elements arranged side by side in the arrangement direction, the first to third extended portions being arranged at the shoulder portion of the second conductor spaced apart from one another in the width direction and respectively extending in the arrangement direction, the third extended portion electrically connecting the plurality of second semiconductor elements to the second terminal,
the semiconductor device further comprises a third terminal and a third conductor, the third terminal is located on one side of the third conductor in the arrangement direction that is the same side as the one side of the first conductor, and
the third conductor has a shoulder portion that extends in the width direction, and two extended portions arranged at the shoulder portion thereof spaced apart from each other in the width direction, the two extended portions of the third conductor respectively extending in the arrangement direction and being electrically connected to the plurality of second semiconductor elements by wiring.
